(19) United States
(12) Patent Application Publication
(10) Pub. No.: US 2026/0246267 A1
(43) Pub. Date: Aug. 20, 2026

(54) METHOD FOR CONTROLLING LEVEL SHIFTER AS INPUT TOLERANCE INPUT/OUTPUT LEVEL SHIFTER, AND ASSOCIATED APPARATUS

(71) Applicant: Faraday Technology Corp., Hsin-Chu City (TW)

(72) Inventors: Hung-Jen Liao, Hsin-Chu City (TW); Zhou-Lun Liu, Hsin-Chu City (TW); Meng-Yuan Chen, Hsin-Chu City (TW); Cheng-Yu Hsu, Hsin-Chu City (TW)

(73) Assignee: Faraday Technology Corp., Hsin-Chu City (TW)

(21) Appl. No.: 19/303,397

(22) Filed: Aug. 19, 2025

(30) Foreign Application Priority Data
Feb. 17, 2025 (TW) 114105683

(51) Int. Cl. H02H 9/04; H03K 17/10

(52) U.S. Cl. CPC H02H 9/046; H03K 17/102; H03K 2217/0027

(57) ABSTRACT

A method for controlling a level shifter as an input tolerance input/output (I/O) level shifter and associated apparatus are provided, where the input tolerance I/O level shifter is arranged to couple an I/O pad to a buffering circuit within an input receiver circuit. The method may include performing voltage-detection-based gate bias control on a first N-type transistor within the input tolerance I/O level shifter, including: performing at least one voltage detection operation on a received voltage level on the I/O pad to generate at least one voltage detection result, for generating a self-control signal corresponding to the aforementioned at least one voltage detection result to perform gate bias control; and according to the aforementioned at least one voltage detection result, selectively performing a level-down operation to generate a level-down voltage as the self-control signal according to the received voltage level, for controlling a gate bias of the first N-type transistor.

### BACKGROUND OF THE INVENTION

### 1. Field of the Invention

The present invention is related to circuit control, and more particularly to a method for controlling a level shifter as an input tolerance input/output (I/O) level shifter, as well as associated apparatus.

### 2. Description of the Prior Art

According to the related art, I/O devices may operate at various nominal voltage levels, for example, some newer-generation I/O devices may operate at a nominal voltage of 1.8 volts (V), while some legacy I/O devices may operate at a nominal voltage of 3.3 V. To maintain compatibility with legacy systems, it is desirable for input tolerance cells to operate at a higher voltage level than/beyond the nominal voltage. For example, when the nominal voltage of an I/O device is 1.8 V, it may be expected to interface with a 3.3V voltage interface. However, regarding device reliability, as the 1.8V I/O devices in the input tolerance cells may be exposed to excessive voltage differences or electrical stress in transient behaviors, the 1.8V I/O devices may be seriously degraded, resulting in a shortened lifetime. Specifically, there may be some issues such as time-dependent oxide breakdown (TDDB) and hot carrier injection (HCI). Thus, a novel method and associated architecture are needed for solving the problems without introducing any side effect or in a way that is less likely to introduce a side effect.

### SUMMARY OF THE INVENTION

It is an objective of the present invention to provide a method for controlling a level shifter as an input tolerance I/O level shifter, as well as associated apparatus, in order to solve the problems in the related art.

At least one embodiment of the present invention provides an apparatus for controlling a level shifter as an input tolerance I/O level shifter, and the input tolerance I/O level shifter can be configured to couple an I/O pad to a buffering circuit within an input receiver circuit, to serve as a sub-circuit of the input receiver circuit. The apparatus may comprise a voltage-detection-based gate bias control circuit that is arranged to perform voltage-detection-based gate bias control on a first N-type transistor within the input tolerance I/O level shifter, where a second N-type transistor within the input tolerance I/O level shifter is coupled to the first N-type transistor, and a gate of the second N-type transistor is coupled to a power voltage. In addition, the voltage-detection-based gate bias control circuit may comprise a voltage detection and control circuit coupled to the I/O pad, and a level-down device that is coupled to the voltage detection and control circuit and a gate of the first N-type transistor. For example, the voltage detection and control circuit may be configured to perform at least one voltage detection operation on a received voltage level on the I/O pad to generate at least one voltage detection result, for generating a self-control (or autonomous-control) signal corresponding to the aforementioned at least one voltage detection result to perform gate bias control, where the aforementioned at least one voltage detection result indicates whether the received voltage level corresponds to a logic high state or a logic low state; and the level-down device may be configured to, based on the aforementioned at least one voltage detection result, selectively perform a level-down operation to generate a level-down voltage as the self-control signal according to the received voltage level, for controlling a gate bias of the first N-type transistor.

At least one embodiment of the present invention provides a method for controlling a level shifter as an input tolerance I/O level shifter, and the input tolerance I/O level shifter can be configured to couple an I/O pad to a buffering circuit within an input receiver circuit, to serve as a sub-circuit of the input receiver circuit. The method may comprise performing voltage-detection-based gate bias control on a first N-type transistor within the input tolerance I/O level shifter, where a second N-type transistor within the input tolerance I/O level shifter is coupled to the first N-type transistor, and a gate of the second N-type transistor is coupled to a power voltage. For example, performing the voltage-detection-based gate bias control on the first N-type transistor within the input tolerance I/O level shifter may further comprise: performing at least one voltage detection operation on a received voltage level on the I/O pad to generate at least one voltage detection result, for generating a self-control signal corresponding to the aforementioned at least one voltage detection result to perform gate bias control, where the aforementioned at least one voltage detection result indicates whether the received voltage level corresponds to a logic high state or a logic low state; and based on the aforementioned at least one voltage detection result, selectively performing a level-down operation to generate a level-down voltage as the self-control signal according to the received voltage level, for controlling a gate bias of the first N-type transistor.

It is an advantage of the present invention that, through proper design, the method of the present invention and the associated apparatus can dynamically manage the input receiver circuit to make the input receiver circuit operate correctly in various situations. For example, when the nominal voltage of an I/O device is 1.8 V, it can be arranged to interface with a 1.8V voltage interface and can also be arranged to interface with a 3.3V voltage interface, for reducing the associated costs. More particularly, as time goes by, the method of the present invention and the associated apparatus can ensure long-term reliability of the input receiver circuit to operate correctly without severe degradation. In addition, the method of the present invention and the associated apparatus can solve the problems in the related art without introducing any side effect or in a way that is less likely to introduce a side effect.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating an apparatus for controlling a level shifter as an input tolerance I/O level shifter according to an embodiment of the present invention, where the apparatus can operate in accordance with a method for controlling a level shifter as an input tolerance I/O level shifter.

FIG. 2 illustrates a single-transistor level shifter control scheme.

FIG. 3 illustrates a multi-transistor level shifter control scheme of the method according to an embodiment of the present invention.

FIG. 4 illustrates a hardware architecture involved with the multi-transistor level shifter control scheme shown in FIG. 3 according to an embodiment of the present invention.

FIG. 5 illustrates, in the lower half part thereof, a multi-transistor architecture normal voltage configuration involved with the multi-transistor level shifter control scheme shown in FIG. 3 according to an embodiment of the present invention, where a single-transistor architecture normal voltage configuration involved with the single-transistor level shifter control scheme shown in FIG. 2 may be illustrated in the upper half part of FIG. 5 for better comprehension.

FIG. 6 illustrates, in the lower half part thereof, the associated signals of the multi-transistor architecture normal voltage configuration shown in the lower half part of FIG. 5 according to an embodiment of the present invention, where the associated signals of the single-transistor architecture normal voltage configuration shown in the upper half part of FIG. 5 may be illustrated in the upper half part of FIG. 6 for better comprehension.

FIG. 7 illustrates, in the lower half part thereof, a multi-transistor architecture abnormal voltage configuration involved with the multi-transistor level shifter control scheme shown in FIG. 3 according to an embodiment of the present invention, where a single-transistor architecture abnormal voltage configuration involved with the single-transistor level shifter control scheme shown in FIG. 2 may be illustrated in the upper half part of FIG. 7 for better comprehension.

FIG. 8 illustrates, in the lower half part thereof, the associated signals of the multi-transistor architecture abnormal voltage configuration shown in the lower half part of FIG. 7 according to an embodiment of the present invention, where the associated signals of the single-transistor architecture abnormal voltage configuration shown in the upper half part of FIG. 7 may be illustrated in the upper half part of FIG. 8 for better comprehension.

FIG. 9 illustrates the associated signals of the multi-transistor architecture abnormal voltage configuration shown in the lower half part of FIG. 7 according to another embodiment of the present invention.

FIG. 10 illustrates a working flow of the method according to an embodiment of the present invention.

### DETAILED DESCRIPTION

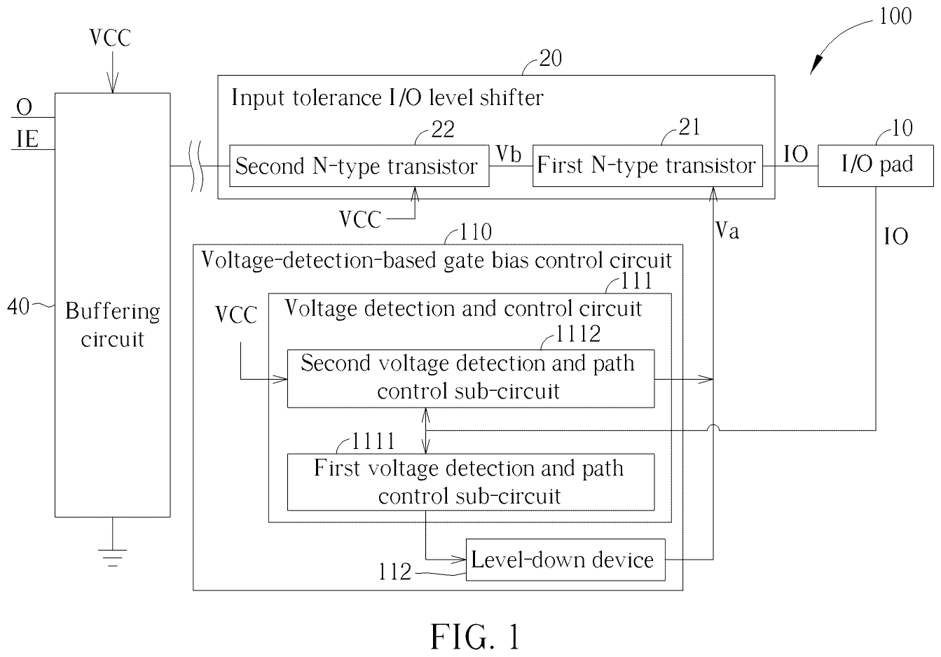

FIG. 1 is a schematic diagram illustrating an apparatus 100 for controlling a level shifter (e.g., a level shifter equipped with at least two transistors) as an input tolerance I/O level shifter 20 according to an embodiment of the present invention, where the apparatus 100 can operate in accordance with a method for controlling a level shifter as an input tolerance I/O level shifter. The input tolerance I/O level shifter 20 can be arranged to couple an I/O pad 10 to a buffering circuit 40 (e.g., an I/O buffering circuit) within an input receiver circuit, to serve as a sub-circuit of the input receiver circuit. According to some embodiments, multiple sub-circuits of the input receiver circuit may comprise the I/O pad 10, the input tolerance I/O level shifter 20, the buffering circuit 40, etc. on a receiving path of the input receiver circuit, and the apparatus 100 may comprise at least one portion of sub-circuits (e.g., a portion of sub-circuits, or all sub-circuits) among the multiple sub-circuits. For example, apparatus 100 may comprise the whole of the input receiver circuit, and more particularly, may represent the input receiver circuit, but the present invention is not limited thereto.

As shown in FIG. 1, the apparatus 100 may comprise a voltage-detection-based gate bias control circuit 110 that is arranged to perform voltage-detection-based gate bias control on a first N-type transistor 21 within the input tolerance I/O level shifter 20, where a second N-type transistor 22 within the input tolerance I/O level shifter 20 is coupled to the first N-type transistor 21, and a gate (not shown in FIG. 1) of the second N-type transistor 22 is coupled to a power voltage VCC. In addition, the voltage-detection-based gate bias control circuit 110 may comprise a voltage detection and control circuit 111 that is coupled to the I/O pad 10, and a level-down device 112 that is coupled to the voltage detection and control circuit 111 and a gate (not shown in FIG. 1) of the first N-type transistor 21. The voltage detection and control circuit 111 may comprise a first voltage detection and path control sub-circuit 1111 and a second voltage detection and path control sub-circuit 1112.

The voltage detection and control circuit 111 can perform at least one voltage detection operation (e.g., one or more voltage detection operations) on a received voltage level IO on the I/O pad 10 to generate at least one voltage detection result (e.g., one or more voltage detection results), for generating a self-control signal Va (which can be a control signal for autonomous control comprising the voltage-detection-based gate bias control within the apparatus 100, and therefore can also be referred to as “the autonomous-control signal Va”) corresponding to the aforementioned at least one voltage detection result to perform gate bias control, where the aforementioned at least one voltage detection result indicates whether the received voltage level IO corresponds to a logic high state or a logic low state. Based on the aforementioned at least one voltage detection result, the level-down device 112 can selectively perform a level-down operation to generate a level-down voltage as the self-control signal Va according to the received voltage level IO, for controlling a gate bias of the first N-type transistor 21. For better comprehension, when the received voltage level IO is in the logic high state, the received voltage level IO may be equal to a predetermined higher voltage IO_{H}. When the received voltage level IO is in the logic low state, the received voltage level IO may be equal to a predetermined lower voltage IO_{L}, where the predetermined lower voltage IO_{L} may be a ground voltage. For example, regarding an application in which the predetermined higher voltage IO_{H} is equal to the power voltage VCC, IO_{H}=VCC=1.8 V and IO_{L}=0 V, and, regarding an application in which the predetermined higher voltage IO_{H} is greater than the power voltage VCC, IO_{H}=3.3 V>VCC=1.8 V and IO_{L}=0 V, but the present invention is not limited thereto. In some examples, the power voltage VCC, the predetermined higher voltage IO_{H}, and/or the predetermined lower voltage IO_{L} may vary.

The first voltage detection and path control sub-circuit 1111 can selectively enable a signal path between the I/O pad 10 and the level-down device 112 according to the aforementioned at least one voltage detection result, to allow the level-down device 112 to perform the level-down operation to generate the level-down voltage as the self-control signal Va, and the second voltage detection and path control sub-circuit 1112 can selectively disable a power path between the power voltage VCC and an output terminal of the level-down device 112 according to the aforementioned at least one voltage detection result, to allow the level-down device 112 to correctly output the level-down voltage as the self-control signal Va without being affected by the power voltage VCC. In particular, the aforementioned at least one voltage detection result may comprise a first voltage detection result at a first time point and a second voltage detection result at a second time point, where the first voltage detection result indicates that the received voltage level IO corresponds to the logic high state, and the second voltage detection result indicates that the received voltage level IO corresponds to the logic low state. For example, the first voltage detection and path control sub-circuit 1111 can enable the signal path according to the first voltage detection result at the first time point, to allow the level-down device 112 to perform the level-down operation to generate the level-down voltage as the self-control signal Va, and the second voltage detection and path control sub-circuit 1112 can disable the power path according to the first voltage detection result at the first time point, to allow the level-down device 112 to correctly output the level-down voltage as the self-control signal Va without being affected by the power voltage VCC. In addition, the first voltage detection and path control sub-circuit 1111 can disable the signal path according to the second voltage detection result at the second time point, to prevent the level-down device 112 from performing the level-down operation, and the second voltage detection and path control sub-circuit 1112 can enable the power path according to the second voltage detection result at the second time point, to generate the self-control signal Va according to the power voltage VCC.

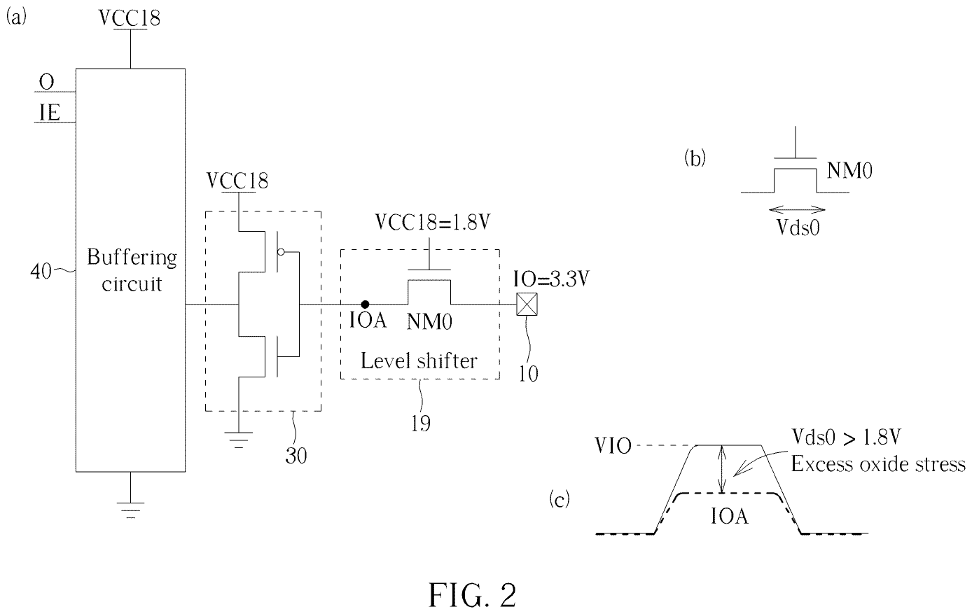

Based on the architecture shown in FIG. 1, the apparatus 100 operating according to the method can dynamically manage the input receiver circuit to make the input receiver circuit operate correctly in various situations. For better comprehension, FIG. 2 illustrates a single-transistor level shifter control scheme, where the power voltage VCC18 can be taken as an example of the power voltage VCC mentioned above, and VCC18=1.8 V. Assuming that the voltage applied across the drain and the source of any N-type transistor NM can be referred to as the drain-to-source voltage Vds, such as the drain-to-source voltage Vds(NM) corresponding to the aforementioned any N-type transistor NM, in a situation where the level shifter 19 is merely equipped with a single transistor such as the N-type transistor NM0 shown in the sub-diagram (a), the drain-to-source voltage Vds(NM0) of the N-type transistor NM0 can be written as the drain-to-source voltage Vds0 shown in the sub-diagram (b). When the received voltage level IO is equal to a predetermined voltage level VIO such as 3.3 V (e.g., IO=3.3 V), the drain-to-source voltage Vds0 of the N-type transistor NM0 can be equal to the voltage difference between the received voltage level IO (in particular, the predetermined voltage level VIO) and the voltage level of the intermediate signal voltage level IOA on the input terminal of the pre-driving circuit 30 (or the output terminal of the level shifter 19). When IO=3.3V, IOA=1.8V−Vtn, where “Vtn” may represent the threshold voltage (or turn-on voltage) of the N-type transistor NM. Depending on process variations, if Vtn>0.3V, it is possible that Vds>1.8V, which indicates that there is a reliability issue; in particular, as shown in the sub-diagram (c), Vds0>1.8 V, and thus there is excess oxide stress. In contrast, the method and the apparatus 100 of the present invention can dynamically manage the input receiver circuit to make the input receiver circuit operate correctly in various situations.

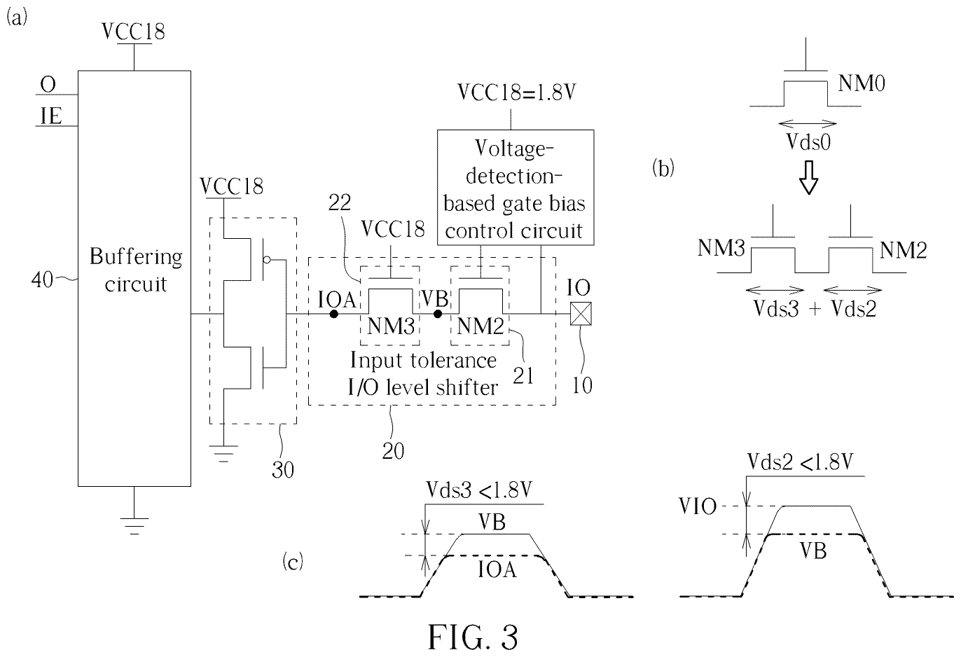

FIG. 3 illustrates a multi-transistor level shifter control scheme of the method according to an embodiment of the present invention, where the power voltage VCC18 can be taken as an example of the power voltage VCC mentioned above, VCC18=1.8 V, and the intermediate signal VB can be taken as an example of the intermediate signal Vb shown in FIG. 1. As shown in the sub-diagram (a), the multiple sub-circuits of the input receiver circuit may comprise the I/O pad 10, the input tolerance I/O level shifter 20, the pre-driving circuit 30, the buffering circuit 40, etc. on the receiving path, and the voltage-detection-based gate bias control circuit 110 can be integrated into/onto the receiving path as one of the multiple sub-circuits. The first N-type transistor 21 and the second N-type transistor 22 can be implemented as the N-type transistors NM2 and NM3, respectively. In a situation where the input tolerance I/O level shifter 20 is equipped with multiple transistors such as the N-type transistors NM2 and NM3, the drain-to-source voltages Vds(NM2) and Vds(NM3) of the N-type transistors NM2 and NM3 can be written as the drain-to-source voltages Vds2 and Vds3 shown in the sub-diagram (b). The N-type transistors NM2 and NM3 are capable of dividing the excessive voltage into two voltages to bear (labeled “Vds3+Vds2” in the sub-diagram (b) for brevity). When the received voltage level IO is equal to the predetermined voltage level VIO such as 3.3 V (e.g., IO=3.3 V), the drain-to-source voltage Vds2 of the N-type transistor NM2 can be equal to the voltage difference between the received voltage level the received voltage level IO (in particular, the predetermined voltage level VIO) and the voltage level of the intermediate signal VB, and the drain-to-source voltage Vds3 of the N-type transistor NM3 can be equal to the voltage difference between the voltage level of the intermediate signal VB and the voltage level of the intermediate signal IOA on the input terminal of the pre-driving circuit 30 (or the output terminal of the input tolerance I/O level shifter 20). As shown in the sub-diagram (c), Vds2<1.8 V and Vds3<1.8 V, and thus there is no issue of excess oxide stress.

For example, when the nominal voltage of an I/O device is 1.8 V, it can be arranged to interface with a 1.8V voltage interface and can also be arranged to interface with a 3.3V voltage interface, for reducing the associated costs. More particularly, as time goes by, the method and the apparatus 100 of the present invention can ensure long-term reliability of the input receiver circuit to operate correctly without severe degradation.

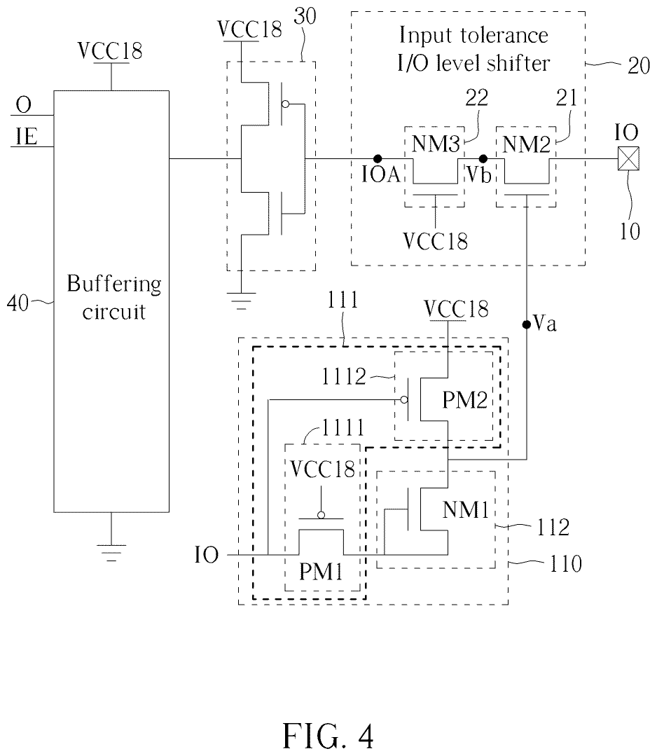

FIG. 4 illustrates a hardware architecture involved with the multi-transistor level shifter control scheme shown in FIG. 3 according to an embodiment of the present invention, where the transistors (e.g., the N-type transistors and the P-type transistors) in the hardware architecture may be metal-oxide-semiconductor field-effect transistors (MOSFETs), such as N-type MOSFETs (or “NMOSFET”) and P-type MOSFETs (or “PMOSFET”), but the present invention is not limited thereto. As long as the implementation of the present invention will not be hindered, the types of these transistors may vary. In addition, the input receiver circuit may set an input enable signal IE as the input enable/disable state (e.g., either the input enable state or the input disable state) thereof, for indicating whether data buffering for the receiving path is enabled. When the input enable signal IE is set as the input enable state, the buffering circuit 40 can perform the data buffering for the receiving path, in order to output the received data to a subsequent stage of circuit, such as a data processing circuit, through the data output signal O.

The partial hardware architecture regarding the voltage-detection-based gate bias control circuit 110 can be described as follows. In the voltage detection and control circuit 111, the first voltage detection and path control sub-circuit 1111 may comprise a first switch coupled to the I/O pad 10, such as a P-type transistor PM1, for selectively enabling the signal path according to the aforementioned at least one voltage detection result, to allow the level-down device 112 to perform the level-down operation to generate the level-down voltage as the self-control signal Va, and the second voltage detection and path control sub-circuit 1112 may comprise a second switch coupled to the I/O pad 10, such as a P-type transistor PM2, for selectively disabling the power path according to the aforementioned at least one voltage detection result, to allow the level-down device 112 to correctly output the level-down voltage as the self-control signal Va without being affected by the power voltage VCC such as the power voltage VCC18. As shown in FIG. 4, the gate of the first P-type transistor PM1 and the gate of the second P-type transistor PM2 are coupled to the power voltage VCC18 and the I/O pad 10, respectively, the source (e.g., the terminal toward the left-hand side) of the first P-type transistor PM1 and the source (e.g., the terminal directed upward, toward the top) of the second P-type transistor PM2 are coupled to the I/O pad 10 and the power voltage VCC18, respectively, and the drain of the first P-type transistor PM1 and the drain of the second P-type transistor PM2 are coupled to an input terminal (e.g., the left-hand terminal) of the level-down device 112 and the output terminal (e.g., the top/upper terminal) of the level-down device 112, respectively.

In addition, the level-down device 112 may comprise a diode-connected transistor coupled to the voltage detection and control circuit 111 and the gate of the first N-type transistor 21 (e.g., the N-type transistor NM2), such as an N-type transistor NM1, for performing the level-down operation to generate the level-down voltage as the self-control signal Va. The drain (e.g., the terminal directed downward, toward the bottom) and the gate of the N-type transistor NM1 are electrically connected to each other and coupled to the signal path (between the I/O pad 10 and the level-down device 112), such as the signal path passing through the source and the drain of P-type transistor PM1, and the source (e.g., the terminal directed upward, toward the top) of the N-type transistor NM1 is coupled to the power path (between the power voltage VCC18 and the level-down device 112), such as the power path passing through the source and the drain of the P-type transistor PM2.

For example, when IO=0 V, the associated operations may comprise:
(1) the first voltage detection and path control sub-circuit 1111 (or the P-type transistor PM1 therein) may disable the signal path according to the second voltage detection result at the second time point, to prevent the level-down device 112 from performing the level-down operation, and the second voltage detection and path control sub-circuit 1112 (or the P-type transistor PM2 therein) may enable the power path according to the second voltage detection result at the second time point, to generate the self-control signal Va according to the power voltage VCC;
(2) the second voltage detection and path control sub-circuit 1112 (or the P-type transistor PM2 therein) may conduct the power voltage VCC18 (e.g., VCC18=1.8 V) to the bottom/lower terminal thereof to generate the self-control signal Va, where in comparison with the power voltage VCC18, the self-control signal Va may have a slight voltage drop; and
(3) under the control of the voltage-detection-based gate bias control circuit 110, when IO=0 V, in the input tolerance I/O level shifter 20, Vds2=Vds3=0 V, and there is no need to worry about the reliability.

In another example, when IO=3.3 V, the associated operations may comprise:
(1) the first voltage detection and path control sub-circuit 1111 (or the P-type transistor PM1 therein) may enable the signal path according to the first voltage detection result at the first time point, to allow the level-down device 112 to perform the level-down operation to generate the level-down voltage as the self-control signal Va, and the second voltage detection and path control sub-circuit 1112 (or the P-type transistor PM2 therein) may disable the power path according to the first voltage detection result at the first time point, to allow the level-down device 112 to correctly output the level-down voltage as the self-control signal Va without being affected by the power voltage VCC;
(2) the first voltage detection and path control sub-circuit 1111 (or the P-type transistor PM1 therein) and the level-down device 112 (or the N-type transistor NM1 therein) may conduct the received voltage level IO (e.g., IO=3.3 V) to the output terminal of the level-down device 112 to generate the level-down voltage as the self-control signal Va, where in comparison with the received voltage level IO, the intermediate signal on the input terminal of the level-down device 112 may have a very small voltage drop, which may be ignored, and, in comparison with this intermediate signal, the self-control signal Va may have a slight voltage drop which is equal to Vtn, and therefore the voltage level of the self-control signal Va may be regarded as being equal to (3.3V−Vtn); and
(3) under the control of the voltage-detection-based gate bias control circuit 110, when IO=3.3 V, in the input tolerance I/O level shifter 20, Vds2<1.8 V and Vds3<1.8 V, and there is no need to worry about the reliability, where the voltage level of the intermediate signal Vb may be equal to (3.3V−(2*Vtn)), the drain-to-source voltage Vds2 (or the drain-to-source voltage Vds(NM2)) may be equal to (2*Vtn), and the drain-to-source voltage Vds3 (or the drain-to-source voltage Vds(NM3)) may be equal to (1.5V−Vtn).

For example, the threshold voltage Vtn may be equal to 0.5 V, but the present invention is not limited thereto. As long as the implementation of the present invention will not be hindered, the threshold voltage Vtn may be equal to any value among various values, such as 0.3 V, 0.5 V, 0.7 V, etc.

Based on the hardware architecture shown in FIG. 4, the self-control signal Va is received as the gate bias of the first N-type transistor 21 (e.g., the N-type transistor NM2), and the input tolerance I/O level shifter 20 is coupled to the voltage-detection-based gate bias control circuit 110 to receive the self-control signal Va in order to operate according to the self-control signal Va, where the self-control signal Va is associated with the received voltage level IO. Since the self-control signal Va is generated by the voltage-detection-based gate bias control circuit 110 according to the received voltage level IO, rather than being generated by any other circuit, the voltage-detection-based gate bias control circuit 110 can operate automatically and independently. As a result, the apparatus 100 operating according to the method can function smoothly without additional control, making the entire hardware architecture very compact while maintaining extremely high performance.

According to some embodiments, the hardware architecture shown in FIG. 4 may vary. For example, the diode-connected transistor may be implemented as a P-type transistor, where the drain and the gate of the P-type transistor are electrically connected to each other and coupled to the power path, and the source of the P-type transistor is coupled to the signal path.

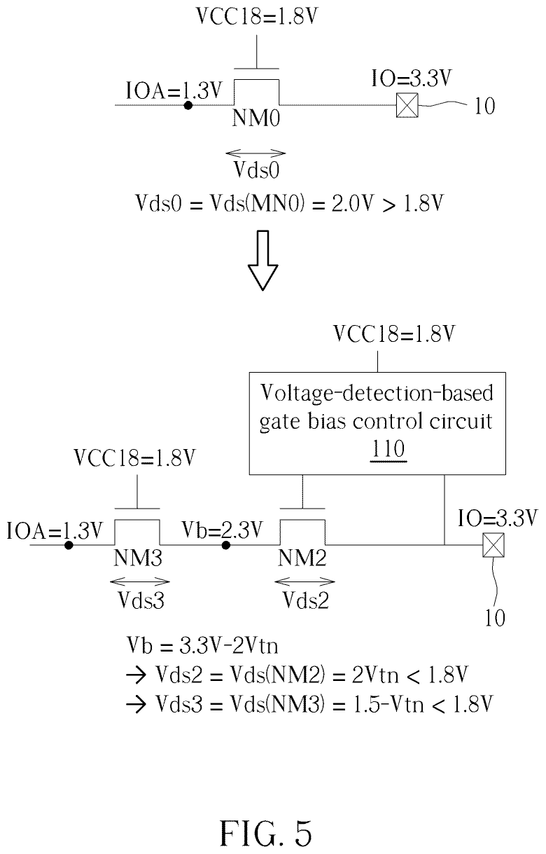

Regarding the first voltage detection result at the first time point, such as the first voltage detection result indicating that the received voltage level IO corresponds to the logic high state, the received voltage level IO may equal the predetermined voltage level VIO such as 3.3 V (e.g., IO=3.3 V), in particular, at the first time point, the power voltage VCC such as VCC18 is less than the received voltage level IO. FIG. 5 illustrates, in the lower half part thereof, a multi-transistor architecture normal voltage configuration involved with the multi-transistor level shifter control scheme shown in FIG. 3 according to an embodiment of the present invention, where a single-transistor architecture normal voltage configuration involved with the single-transistor level shifter control scheme shown in FIG. 2 may be illustrated in the upper half part of FIG. 5 for better comprehension. Regarding the same conditions, for example, at the operating frequency of 150 megahertz (MHz), the process corresponding to PTNT, the voltage of Normal Voltage (NV), and the temperature of 25° C.:
(1) the single-transistor architecture normal voltage configuration shown in the upper half part of FIG. 5 will have a reliability issue, where Vds0=Vds(MN0)=2.0V>1.8V; and
(2) the multi-transistor architecture normal voltage configuration shown in the lower half part of FIG. 5 will not have a reliability issue, where Vb=(3.3V−(2*Vtn)), so Vds2=Vds(NM2)=(2*Vtn)<1.8 V and Vds3=Vds(NM3)=(1.5V−Vtn)<1.8 V.

For better comprehension, some implementation details can be further described as follows. Multiple corner cases related to the process variation may comprise PTNT, PFNF, PSNS, PFNS, and PSNF (or TT, FF, SS, FS, and SF), any of which may be arranged to define the operating speeds of the PMOSFETs and the NMOSFETs, respectively, where “F” stands for Fast, “T” stands for Typical, and “S” stands for Slow. In accordance with voltage variations (e.g., from −10% to +10%) and temperature variations (e.g., from −40° C. to 125° C.), there may be different combinations. Common combinations may comprise:
(1) Typical Case (TC): TT, VCC, 25° C.;
(2) Worst Case (WC): SS, VCC with −10% variation, 125° C.; and
(3) Best Case (BC): FF, VCC with +10% variation, −40° C.

Taking VCC18=1.8V as example, the NV is 1.8V. Theoretically, when VCC18=1.98V, there can be more severe reliability issues in the single-transistor architecture.

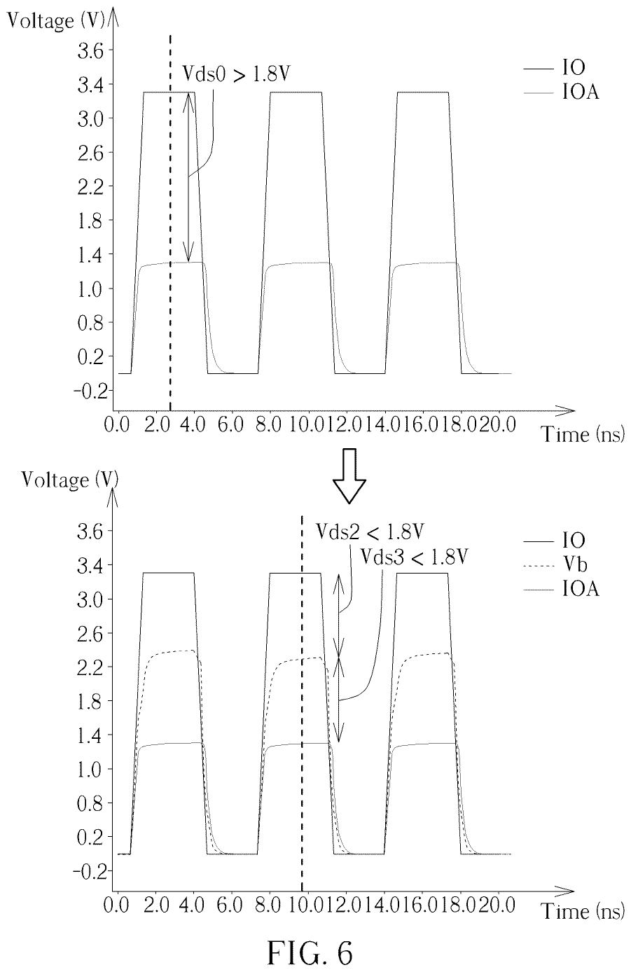

FIG. 6 illustrates, in the lower half part thereof, the associated signals of the multi-transistor architecture normal voltage configuration shown in the lower half part of FIG. 5 according to an embodiment of the present invention, where the associated signals of the single-transistor architecture normal voltage configuration shown in the upper half part of FIG. 5 may be illustrated in the upper half part of FIG. 6 for better comprehension. The horizontal axis represents time, in unit of nanoseconds (ns), and the vertical axis represents voltage, in unit of volts (V). As shown in the upper half part of FIG. 6, Vds0>1.8 V, which indicates that there will be a reliability issue. As shown in the lower half part of FIG. 6, Vds2<1.8 V and Vds3<1.8 V, which indicates that no reliability issue will occur.

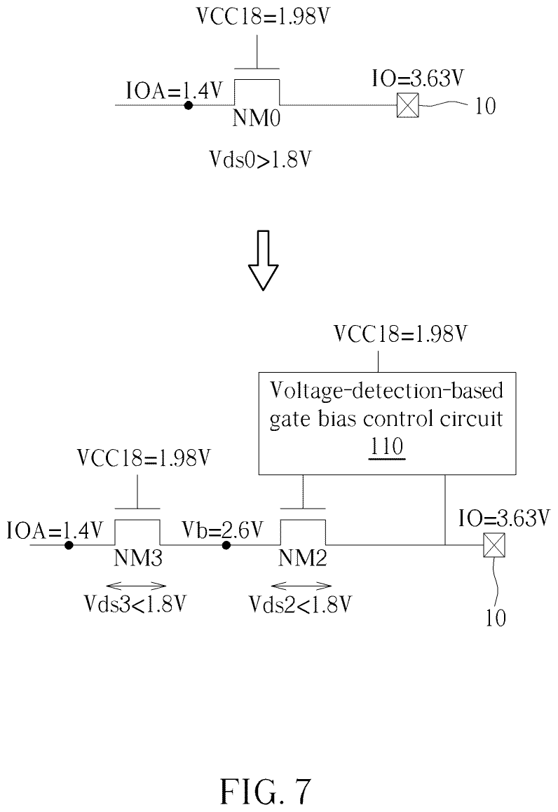

FIG. 7 illustrates, in the lower half part thereof, a multi-transistor architecture abnormal voltage configuration involved with the multi-transistor level shifter control scheme shown in FIG. 3 according to an embodiment of the present invention, where a single-transistor architecture abnormal voltage configuration involved with the single-transistor level shifter control scheme shown in FIG. 2 may be illustrated in the upper half part of FIG. 7 for better comprehension. Regarding the same conditions, for example, at the operating frequency of 150 MHz, the process corresponding to PTNT, the voltage of High Voltage (HV), and the temperature of −40° C.:
(1) the single-transistor architecture abnormal voltage configuration shown in the upper half part of FIG. 7 will have a reliability issue, where Vds0>1.8 V; and
(2) the multi-transistor architecture abnormal voltage configuration shown in the lower half part of FIG. 7 will not have a reliability issue, where Vds2<1.8 V and Vds3<1.8 V.

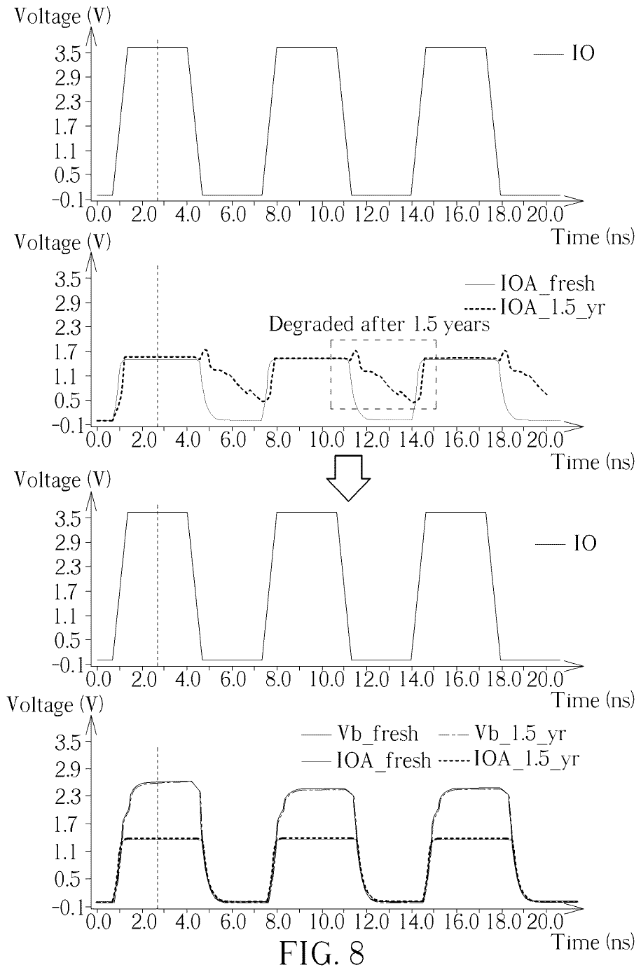

FIG. 8 illustrates, in the lower half part thereof, the associated signals of the multi-transistor architecture abnormal voltage configuration shown in the lower half part of FIG. 7 according to an embodiment of the present invention, where the associated signals of the single-transistor architecture abnormal voltage configuration shown in the upper half part of FIG. 7 may be illustrated in the upper half part of FIG. 8 for better comprehension. As shown in the upper half part of FIG. 8, the intermediate signal IOA may significantly change over time, and more particularly, change from the intermediate signal IOA_fresh, such as the intermediate signal IOA_fresh corresponding to the time when the product is newly shipped, to the intermediate signal IOA_1.5_yr corresponding to a time 1.5 years later, indicating that there will be a reliability issue, where the abnormal curve of IOA_1.5_yr indicates the degradation of the N-type transistor NM0 after 1.5 years. As shown in the lower half part of FIG. 8, the intermediate signals Vb and IOA do not significantly change over time, in particular, they remain unchanged from the intermediate signal Vb_fresh and IOA_fresh, such as the intermediate signal Vb_fresh and IOA_fresh corresponding to the time when the product is newly shipped, to the intermediate signal Vb_1.5_yr and IOA_1.5_yr corresponding to a time 1.5 years later, respectively, indicating that there is no reliability issue.

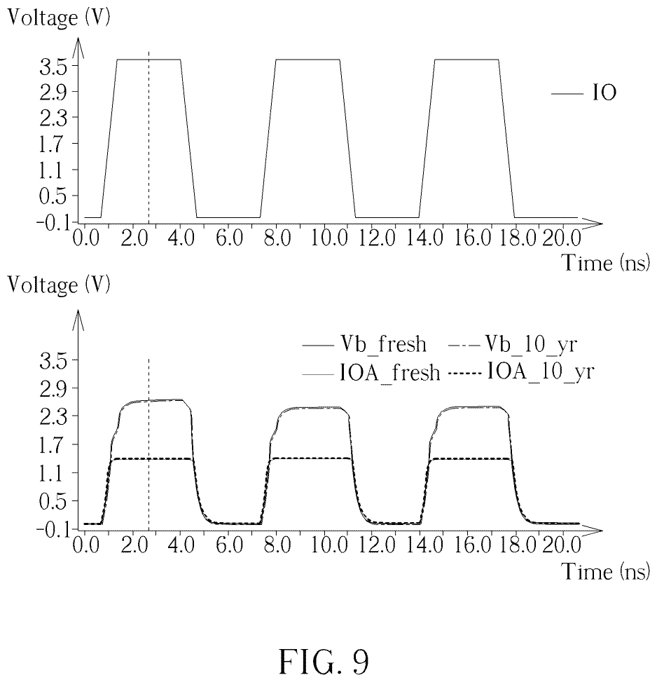

FIG. 9 illustrates the associated signals of the multi-transistor architecture abnormal voltage configuration shown in the lower half part of FIG. 7 according to another embodiment of the present invention. As shown in FIG. 9, the intermediate signals Vb and IOA do not significantly change over time, in particular, they remain unchanged from the intermediate signal Vb_fresh and IOA_fresh, such as the intermediate signal Vb_fresh and IOA_fresh corresponding to the time when the product is newly shipped, to the intermediate signal Vb_10_yr and IOA_10_yr corresponding to a time 10 years later, respectively, indicating that there are is reliability issue.

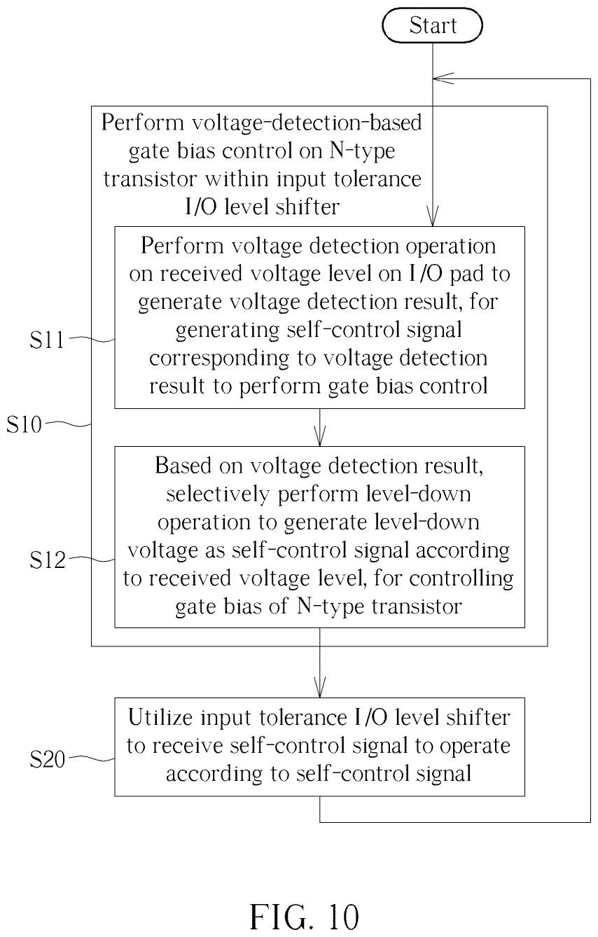

FIG. 10 illustrates a working flow of the method according to an embodiment of the present invention. The apparatus 100 (or the components therein) can operate based on the workflow shown in FIG. 10.

In Step S10, the voltage-detection-based gate bias control circuit 110 can perform voltage-detection-based gate bias control on the first N-type transistor 21 within the input tolerance I/O level shifter 20. Step S10 may comprise multiple sub-steps such as Step S11 and Step S12.

In Step S11, the voltage detection and control circuit 111 can perform a voltage detection operation (e.g., any voltage detection operation among the aforementioned at least one voltage detection operation) on the received voltage level IO on the I/O pad 10 to generate a voltage detection result (e.g., the first voltage detection result or the second voltage detection result), for generating the self-control signal Va corresponding to this voltage detection result to perform the gate bias control, where this voltage detection result indicates whether the received voltage level IO corresponds to the logic high state or the logic low state.

In Step S12, based on this voltage detection result (i.e., the voltage detection result that is just obtained in Step S11), the level-down device 112 can selectively perform a level-down operation (e.g., the level-down operation mentioned above) to generate a level-down voltage (e.g., the level-down voltage mentioned above) as the self-control signal Va according to the received voltage level IO, for controlling the gate bias of the first N-type transistor 21.

In Step S20, the apparatus 100 can utilize the input tolerance I/O level shifter 20 to receive the self-control signal Va to operate according to the self-control signal Va. For brevity, similar descriptions for this embodiment are not repeated in detail here.

For better comprehension, the method may be illustrated with the working flow shown in FIG. 10, but the present invention is not limited thereto. According to some embodiments, one or more steps may be added, deleted, or changed in the working flow shown in FIG. 10.

The method and the apparatus 100 of the present invention can be applied to 28 nanometer (nm)/22 nm/14 nm 3.3V bidirectional I/O and input receiver I/O, by using 1.8V I/O devices, and can also be applied to bidirectional I/O and input receiver I/O with signal high voltage tolerance. In addition, the method and apparatus 100 of the present invention (in particular, the voltage-detection-based gate bias control circuit 110 therein) can be widely used for solving the input receiver level shifter reliability issues, and can perform self-control/autonomous-control, autonomously controlling from the I/O pad signals (e.g., the received voltage level IO on the I/O pad 10) for use in high-voltage tolerance input receivers, and utilize the level-down device 112 to generate the gate bias for the first N-type transistor 21 (e.g., the N-type transistor NM2, which can be implemented as an N-type MOSFET), where the lower gate bias can resolve the input receiver level shifter reliability issues better.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An apparatus for controlling a level shifter as an input tolerance input/output (I/O) level shifter, the input tolerance I/O level shifter being arranged to couple an I/O pad to a buffering circuit within an input receiver circuit, to serve as a sub-circuit of the input receiver circuit, the apparatus comprising:
a voltage-detection-based gate bias control circuit, arranged to perform voltage-detection-based gate bias control on a first N-type transistor within the input tolerance I/O level shifter, wherein a second N-type transistor within the input tolerance I/O level shifter is coupled to the first N-type transistor, and a gate of the second N-type transistor is coupled to a power voltage, wherein the voltage-detection-based gate bias control circuit comprises:
a voltage detection and control circuit, coupled to the I/O pad, arranged to perform at least one voltage detection operation on a received voltage level on the I/O pad to generate at least one voltage detection result, for generating a self-control signal corresponding to the at least one voltage detection result to perform gate bias control, wherein the at least one voltage detection result indicates whether the received voltage level corresponds to a logic high state or a logic low state; and
a level-down device, coupled to the voltage detection and control circuit and a gate of the first N-type transistor, arranged to, based on the at least one voltage detection result, selectively perform a level-down operation to generate a level-down voltage as the self-control signal according to the received voltage level, for controlling a gate bias of the first N-type transistor.

2. The apparatus of claim 1, wherein the voltage detection and control circuit comprises:
a first voltage detection and path control sub-circuit, coupled to the I/O pad, arranged to selectively enable a signal path between the I/O pad and the level-down device according to the at least one voltage detection result, to allow the level-down device to perform the level-down operation to generate the level-down voltage as the self-control signal; and
a second voltage detection and path control sub-circuit, coupled to the I/O pad, arranged to selectively disable a power path between the power voltage and an output terminal of the level-down device according to the at least one voltage detection result, to allow the level-down device to correctly output the level-down voltage as the self-control signal without being affected by the power voltage.

3. The apparatus of claim 2, wherein the at least one voltage detection result comprises a first voltage detection result at a first time point, and the first voltage detection result indicates that the received voltage level corresponds to the logic high state, wherein:
the first voltage detection and path control sub-circuit is arranged to enable the signal path according to the first voltage detection result at the first time point, to allow the level-down device to perform the level-down operation to generate the level-down voltage as the self-control signal; and
the second voltage detection and path control sub-circuit is arranged to disable the power path according to the first voltage detection result at the first time point, to allow the level-down device to correctly output the level-down voltage as the self-control signal without being affected by the power voltage.

4. The apparatus of claim 3, wherein the at least one voltage detection result further comprises a second voltage detection result at a second time point, and the second voltage detection result indicates that the received voltage level corresponds to the logic low state, wherein:
the first voltage detection and path control sub-circuit is arranged to disable the signal path according to the second voltage detection result at the second time point, to prevent the level-down device from performing the level-down operation; and
the second voltage detection and path control sub-circuit is arranged to enable the power path according to the second voltage detection result at the second time point, to generate the self-control signal according to the power voltage.

5. The apparatus of claim 2, wherein:
the first voltage detection and path control sub-circuit comprises:
a first switch, coupled to the I/O pad, arranged to selectively enable the signal path according to the at least one voltage detection result, to allow the level-down device to perform the level-down operation to generate the level-down voltage as the self-control signal; and
the second voltage detection and path control sub-circuit comprises:
a second switch, coupled to the I/O pad, arranged to selectively disable the power path according to the at least one voltage detection result, to allow the level-down device to correctly output the level-down voltage as the self-control signal without being affected by the power voltage.

6. The apparatus of claim 5, wherein the first switch and the second switch are implemented as a first P-type transistor and a second P-type transistor, respectively, wherein a gate of the first P-type transistor and a gate of the second P-type transistor are coupled to the power voltage and the I/O pad, respectively, a source of the first P-type transistor and a source of the second P-type transistor are coupled to the I/O pad and the power voltage, respectively, and a drain of the first P-type transistor and a drain of the second P-type transistor are coupled to an input terminal of the level-down device and the output terminal, respectively.

7. The apparatus of claim 1, wherein the at least one voltage detection result comprises a first voltage detection result at a first time point, and the first voltage detection result indicates that the received voltage level corresponds to the logic high state; and at the first time point, the power voltage is less than the received voltage level.

8. The apparatus of claim 1, wherein the level-down device comprises:
a diode-connected transistor, coupled to the voltage detection and control circuit and the gate of the first N-type transistor, arranged to perform the level-down operation to generate the level-down voltage as the self-control signal.

9. The apparatus of claim 8, wherein:
the diode-connected transistor is implemented as a third N-type transistor, wherein a drain and a gate of the third N-type transistor are electrically connected to each other and coupled to a signal path between the I/O pad and the level-down device, and a source of the third N-type transistor is coupled to a power path between the power voltage and the level-down device; or
the diode-connected transistor is implemented as a P-type transistor, wherein a drain and a gate of the P-type transistor are electrically connected to each other and coupled to the power path, and a source of the P-type transistor is coupled to the signal path.

10. The apparatus of claim 1, wherein the self-control signal is received as the gate bias of the first N-type transistor, and the apparatus further comprises:
the input tolerance I/O level shifter, coupled to the voltage-detection-based gate bias control circuit, arranged to receive the self-control signal to operate according to the self-control signal.

11. A method for controlling a level shifter as an input tolerance input/output (I/O) level shifter, the input tolerance I/O level shifter being arranged to couple an I/O pad to a buffering circuit within an input receiver circuit, to serve as a sub-circuit of the input receiver circuit, the method comprising:
performing voltage-detection-based gate bias control on a first N-type transistor within the input tolerance I/O level shifter, wherein a second N-type transistor within the input tolerance I/O level shifter is coupled to the first N-type transistor, and a gate of the second N-type transistor is coupled to a power voltage, wherein performing the voltage-detection-based gate bias control on the first N-type transistor within the input tolerance I/O level shifter further comprises:
performing at least one voltage detection operation on a received voltage level on the I/O pad to generate at least one voltage detection result, for generating a self-control signal corresponding to the at least one voltage detection result to perform gate bias control, wherein the at least one voltage detection result indicates whether the received voltage level corresponds to a logic high state or a logic low state; and
based on the at least one voltage detection result, selectively performing a level-down operation to generate a level-down voltage as the self-control signal according to the received voltage level, for controlling a gate bias of the first N-type transistor.

12. The method of claim 11, wherein a level-down device is arranged to perform the level-down operation; and performing the at least one voltage detection operation on the received voltage level on the I/O pad to generate the at least one voltage detection result for generating the self-control signal corresponding to the at least one voltage detection result to perform the gate bias control further comprises:
selectively enabling a signal path between the I/O pad and the level-down device according to the at least one voltage detection result, to allow the level-down device to perform the level-down operation to generate the level-down voltage as the self-control signal; and
selectively disabling a power path between the power voltage and an output terminal of the level-down device according to the at least one voltage detection result, to allow the level-down device to correctly output the level-down voltage as the self-control signal without being affected by the power voltage.

13. The method of claim 12, wherein the at least one voltage detection result comprises a first voltage detection result at a first time point, and the first voltage detection result indicates that the received voltage level corresponds to the logic high state, wherein:
selectively enabling the signal path between the I/O pad and the level-down device according to the at least one voltage detection result to allow the level-down device to perform the level-down operation to generate the level-down voltage as the self-control signal further comprises:
enabling the signal path according to the first voltage detection result at the first time point, to allow the level-down device to perform the level-down operation to generate the level-down voltage as the self-control signal; and
selectively disabling the power path between the power voltage and the output terminal of the level-down device according to the at least one voltage detection result to allow the level-down device to correctly output the level-down voltage as the self-control signal without being affected by the power voltage further comprises:
disabling the power path according to the first voltage detection result at the first time point, to allow the level-down device to correctly output the level-down voltage as the self-control signal without being affected by the power voltage.

14. The method of claim 13, wherein the at least one voltage detection result further comprises a second voltage detection result at a second time point, and the second voltage detection result indicates that the received voltage level corresponds to the logic low state, wherein:
selectively enabling the signal path between the I/O pad and the level-down device according to the at least one voltage detection result to allow the level-down device to perform the level-down operation to generate the level-down voltage as the self-control signal further comprises:
disabling the signal path according to the second voltage detection result at the second time point, to prevent the level-down device from performing the level-down operation; and
selectively disabling the power path between the power voltage and the output terminal of the level-down device according to the at least one voltage detection result to allow the level-down device to correctly output the level-down voltage as the self-control signal without being affected by the power voltage further comprises:
enabling the power path according to the second voltage detection result at the second time point, to generate the self-control signal according to the power voltage.

15. The method of claim 12, wherein:
selectively enabling the signal path between the I/O pad and the level-down device according to the at least one voltage detection result to allow the level-down device to perform the level-down operation to generate the level-down voltage as the self-control signal further comprises:
utilizing a first switch to selectively enable the signal path according to the at least one voltage detection result, to allow the level-down device to perform the level-down operation to generate the level-down voltage as the self-control signal; and
selectively disabling the power path between the power voltage and the output terminal of the level-down device according to the at least one voltage detection result to allow the level-down device to correctly output the level-down voltage as the self-control signal without being affected by the power voltage further comprises:
utilizing a second switch to selectively disable the power path according to the at least one voltage detection result, to allow the level-down device to correctly output the level-down voltage as the self-control signal without being affected by the power voltage.

16. The method of claim 15, wherein the first switch and the second switch are implemented as a first P-type transistor and a second P-type transistor, respectively, wherein a gate of the first P-type transistor and a gate of the second P-type transistor are coupled to the power voltage and the I/O pad, respectively, a source of the first P-type transistor and a source of the second P-type transistor are coupled to the I/O pad and the power voltage, respectively, and a drain of the first P-type transistor and a drain of the second P-type transistor are coupled to an input terminal of the level-down device and the output terminal, respectively.

17. The method of claim 11, wherein the at least one voltage detection result comprises a first voltage detection result at a first time point, and the first voltage detection result indicates that the received voltage level corresponds to the logic high state; and at the first time point, the power voltage is less than the received voltage level.

18. The method of claim 11, wherein a level-down device is arranged to perform the level-down operation; and the level-down device comprises:
a diode-connected transistor, coupled to the voltage detection and control circuit and a gate of the first N-type transistor, arranged to perform the level-down operation to generate the level-down voltage as the self-control signal.

19. The method of claim 18, wherein:
the diode-connected transistor is implemented as a third N-type transistor, wherein a drain and a gate of the third N-type transistor are electrically connected to each other and coupled to a signal path between the I/O pad and the level-down device, and a source of the third N-type transistor is coupled to a power path between the power voltage and the level-down device; or
the diode-connected transistor is implemented as a P-type transistor, wherein a drain and a gate of the P-type transistor are electrically connected to each other and coupled to the power path, and a source of the P-type transistor is coupled to the signal path.

20. The method of claim 11, wherein the self-control signal is received as the gate bias of the first N-type transistor, and the method further comprises:
utilizing the input tolerance I/O level shifter to receive the self-control signal to operate according to the self-control signal.
